(19) United States
(12) Patent Application Publication
(10) Pub. No.: US 2024/0269908 A1
(43) Pub. Date: Aug. 15, 2024

(54) METHOD FOR MONITORING A DEVICE FOR SUPPLYING TEMPERATURE CONTROL MEDIA TO A MOLD OF A MOLDING MACHINE

(71) Applicant: ENGEL AUSTRIA GmbH, Schwertberg (AT)

(72) Inventors: Mathias SCHLAEGER, Pregarten (AT); Alexander GREISINGER, Ennsdorf (AT)

(21) Appl. No.: 18/437,763

(22) Filed: Feb. 9, 2024

(30) Foreign Application Priority Data
Feb. 10, 2023 (AT) A 50087/2023

(51) Int. Cl. B29C 45/78; B29C 37/00; B29C 45/17; B29C 45/77

(52) U.S. Cl. CPC B29C 45/78; B29C 45/1774; B29C 45/77; B29C 2037/903; B29C 2945/76056; B29C 2945/76531; B29C 2945/76545

(57) ABSTRACT

A method for monitoring a device for supplying temperature control media to a mold of a molding machine, wherein the device has a feed line and a return line between which a temperature control line is arranged, a measuring element arranged in each of the temperature control lines actually to be monitored, and a control element arranged in each temperature control line to be regulated or to be controlled. A pressure drop in the temperature control line is measured, a hydraulic resistance and/or a change in resistance of the temperature control line is calculated based on an a volumetric flow rate measured using the measuring element and based on the measured pressure drop. The degree of opening of the control element is taken into consideration in the calculation of the hydraulic resistance and/or the change in resistance.

The present application claims priority to Austrian Patent Application No. A 50087/20203, filed on Feb. 10, 2023. Thus, all of the subject matter of Austrian Patent Application No. A 50087/2023 is incorporated herein by reference.

### BACKGROUND OF THE INVENTION

The present invention relates to a method for monitoring a device for supplying temperature control media to a mold of a molding machine, a method for monitoring a device for supplying temperature control media to a mold of a molding machine, and a device for performing each of those methods. The invention furthermore relates to a computer program product and a computer-readable storage medium for carrying out a method according to the invention. The invention furthermore relates to a computer-readable data carrier and a data carrier signal for such a computer program product. The invention furthermore relates to a molding machine, in particular an injection-molding machine, with a device according to the invention.

The status of mold temperature control channels, or also other temperature control channels through which media flow in machine components, is dependent on the quality of the temperature control medium flowing through. Over time, the quality of the temperature control medium deteriorates, as a result of which deposits can form in the temperature control circuits. These deposits consist, for example, of rust or limescale, sometimes also called scale. These deposits form a type of insulation layer in the temperature control channel of a mold component. The exchange of heat between the components to be temperature controlled and the medium is thereby negatively influenced, which can lead to undesired temperature changes of the components.

In the example of a mold temperature control channel of an injection-molding machine, the mold cavity wall temperature can alter as a result. An undesired alteration of this temperature can lead to problems on the molded part because the thermal conditions are altered. The consequences can be demolding or quality problems such as warping due to differing shrinkage. Visual surface differences, internal stresses or differences in the crystallization in the case of partially crystalline plastics can also form on the molded part due to altered temperatures in the mold cavity wall. Naturally, other quality problems, such as for example deviation of the dimensions and tolerances are also possible.

Such problems result in disadvantages such as higher costs due to reject parts, higher cost and time expenditures due to servicing that is too frequent or not frequent enough, longer machine times, including longer cooling times, higher staffing costs and/or energy costs.

For these reasons, it is usual to monitor temperature control lines by installing sensors for measuring pressure and/or volumetric flow rate, as is disclosed in the following published documents:
DE 10 2009 051 931 A1, DE 697 06 458 T2, DE 10 2008 003 315 A1, DE 88 02 462 U1 and DE 10 2013 016 773 B4.

In these documents a pressure drop and/or a volumetric flow rate is measured in order to discover deposits and/or blockages in a temperature control media supply unit. If the measured pressures and/or volumetric flow rates are compared with preset target values or previously measured reference values, changes in the temperature control lines caused by deposits, blockages or the like can be discovered.

Currently used methods for identifying deposits and/or blockages have the disadvantage that either the molding tool has to be taken out of service or it is no longer possible to regulate the temperature control media supply unit or individual temperature control channels during ongoing operation.

A further disadvantage of the state of the art is that deposits and/or blockages are only discovered at a late stage. Thus, for example, a thin but elongated insulation layer along a temperature control channel can already result in the above-described disadvantages at an early stage without being discovered by current monitoring methods. Only when the insulation layer has reached an already undesired thickness do current methods detect the deposits.

### SUMMARY OF THE INVENTION

The object of the present invention is therefore to at least partially remedy the disadvantages of the state of the art and to provide a method that is improved compared with the state of the art and is characterized in particular by a reliable discovery of blockages and deposits in the temperature control lines and/or the temperature control channels during ongoing operation.

In addition, a device for carrying out a method according to the invention is to be provided.

The invention brings about an increase in the efficiency of a temperature control media supply unit by ascertaining the status during ongoing operation and by a better planned servicing for a molding tool.

The object is achieved according to a first aspect of the invention by means of a method for monitoring a device for supplying temperature control media to a mold of a molding machine. The device for supplying temperature control media has a feed line and a return line, between which at least one temperature control line is arranged, wherein at least one measuring element, in particular a volumetric flow rate measuring element, is arranged in each of the temperature control lines actually to be monitored, and at least one control element, in particular a volumetric flow valve, is arranged in each temperature control line to be regulated or to be controlled. At least one pressure drop in the at least one temperature control line is measured, at least one hydraulic resistance and/or at least one change in resistance of the at least one temperature control line is calculated on the basis of an at least one volumetric flow rate measured using the at least one measuring element and on the basis of the at least one measured pressure drop, and the degree of opening of the at least one control element is taken into consideration in the calculation of the at least one hydraulic resistance and/or the at least one change in resistance.

In other words, the technical problem is solved by measuring a pressure drop of at least one temperature control line. Each temperature control line to be monitored contains a measuring element, in particular a volumetric flow rate measuring element, and each temperature control line to be regulated or to be controlled additionally contains at least one control element, in particular a volumetric flow valve. Through the simultaneous measurement of a pressure drop and a volumetric flow rate, a hydraulic resistance and/or a change in resistance can be measured in each temperature control line, in particular each temperature control channel of a mold. The degree of opening of the at least one control element is taken into consideration in this hydraulic resistance and/or this change in the hydraulic resistance. It is thereby possible, during ongoing operation, to determine the hydraulic resistances of temperature control lines, in particular of temperature control channels, couplings, hoses and/or the like, to identify deposits and/or blockages therewith and at the same time to conduct the regulation and/or control of the temperature control media supply system.

The object is achieved according to a second aspect of the invention by a method for monitoring a device for supplying temperature control media to a mold of a molding machine. The device for supplying temperature control media has a feed line and a return line, between which at least one temperature control line is arranged, wherein at least one measuring element, in particular a volumetric flow rate measuring element, is arranged in each of the temperature control lines actually to be monitored. At least one temperature change in the at least one temperature control line is measured, and at least one heat flow and/or at least one change in heat flow of the at least one temperature control line is calculated on the basis of an at least one volumetric flow rate measured using the at least one measuring element and on the basis of the at least one temperature change.

In other words, the technical problem is solved by measuring a temperature change of at least one temperature control line. Each temperature control line to be monitored contains a measuring element, in particular a volumetric flow rate measuring element. Through the simultaneous measurement of a temperature change and a volumetric flow rate, a heat flow and/or a change in heat flow can be calculated for each temperature control line, in particular each temperature control circuit of a mold. It is thereby possible to determine the heat flows of temperature control lines, in particular of temperature control channels, couplings, hoses and/or the like, during ongoing operation in order to identify deposits and/or blockages therewith.

A method according to the invention and, building on it, a device, a computer program product, a computer-readable storage medium, a computer-readable data carrier, a data carrier signal, a computer and a molding machine, in particular an injection-molding machine, can be employed through use in already known embodiments of the state of the art, as described in the introduction to the description for example, and installed subsequently.

One advantage of the invention is that deposits and/or blockages can be discovered at an early stage and with certainty by calculating the hydraulic resistance and/or the heat flow and/or a change in the hydraulic resistance and/or the heat flow. Thus, for example, coarse blockages can be detected through the hydraulic resistance and/or the change therein and/or thin-layered but extensive deposits can be identified through the heat flow and/or the change therein.

Further advantages of this invention are that monitoring can be carried out during ongoing operation independently of the degree of opening of the control element and a continuous regulation or control of each temperature control circuit and/or temperature control channel to be regulated or to be controlled is possible.

Moreover, at most two pressure sensors in the central feed line and return line are necessary, instead of two pressure sensors in each case in each individual circuit.

In addition, it is possible to classify the temperature control circuits and thus assign them to a model, for example a CAD model, as a result of which tubing errors can be discovered.

In contrast to the state of the art, a constant and reliable monitoring of the temperature control circuit is possible with this new invention. In addition, using a regulated temperature control media distributor, the influence of a control element present, for example a control valve or regulating valve, can be included in the calculation.

Thus, it is not necessary to use other process settings for the monitoring, control and/or regulation of the temperature control media supply.

Such a temperature control media supply unit is capable of measuring at least one pressure drop and/or one temperature change as well as at least one volumetric flow rate.

In order to be able to measure such a pressure drop, two pressure sensors are to be provided as a rule. A pressure drop can also be measured with only one pressure sensor if, for example, the supply pressure is known and is sufficiently constant.

In order to be able to measure such a temperature change, two temperature sensors are to be provided as a rule. A temperature change can also be measured with only one temperature sensor if, for example, the supply temperature is known and is sufficiently constant.

In order to describe the functioning of the first aspect of the invention below it is assumed that the pressure drop and the volumetric flow rate of at least one temperature control line are measured by two pressure sensors and a further measuring element in this line.

A preferred embodiment with two pressure sensors for measuring a pressure drop and one measuring element for measuring a volumetric flow rate is a proposed structural arrangement which is not to be understood as limitative. Any possible structural measure in which a pressure drop and a volumetric flow rate can be measured out according to a method with the features of claim 1 is conceivable.

It can further be provided that, in addition to the measurement of a volumetric flow rate, a mass flow and/or another value correlating to the volumetric flow rate is also measured and/or calculated with the aid of the volumetric flow rate.

Between the pressure sensors, at least one hydraulic resistance is responsible for the measured pressure drop. As a rule, this hydraulic resistance is the hydraulic resistance of a temperature control channel through a molding tool.

Besides the contribution of a temperature control channel through a molding tool, resistance contributions through tubing, couplings, distributors, further temperature control channels or the like can also be added to a hydraulic resistance of a temperature control line.

In this described case, the segment of the temperature control line which is to be monitored and controlled or regulated additionally contains, between the two pressure sensors, at least one measuring element, in particular a volumetric flow rate measuring device, in particular a volumetric flow rate measuring element, as well as at least one control element, in particular a valve, in particular a volumetric flow valve.

The control element, in particular the volumetric flow valve, can represent an additional hydraulic resistance, wherein the magnitude of the resistance depends above all on the degree of opening of the control element.

The exact placements of the measuring element and of the control element in the temperature control line are not relevant as long as they are installed in the temperature control line to be monitored and to be controlled or to be regulated and are taken into consideration through the measured pressure drop.

The control element can be used for controlling or regulating the volumetric flow rate or a temperature difference in a temperature control channel and/or temperature control circuit. The temperature difference can be determined between the feed line, in particular before the molding tool, and the return line, in particular after the molding tool.

As control variable, the degree of opening of the control element can be altered in order to reach and/or to stabilize a desired target value for a volumetric flow rate or a temperature difference. These parameters are process parameters which can be stored in datasets as target values or monitoring values.

The control element can be connected to a control device and subsequently to a data processing unit, whereby the degree of opening of the control element is constantly known and controllable or regulatable.

It can be provided that the control element has a position feedback which, after an actuated change in the degree of opening of the control element, outputs a signal regarding the control position actually adopted by the control element and/or the actually prevailing degree of opening of the control element.

It can be provided that the control element does not have a position feedback. In this embodiment, after the actuation of the control element, a predefined target value is assumed as the effective actual value of the control element.

If the degree of opening of the control element and the current volumetric flow rate is known, the hydraulic resistance of the control element is thus known. With the aid of the current degree of opening, this hydraulic resistance can either be calculated using a mathematical function and/or retrieved from a database.

The mathematical function for calculating the hydraulic resistance can be an approximation function, for example, which links the hydraulic resistance to the (percentage) degree of opening of the control element via coefficients.

Alternatively or additionally, a pressure drop or a hydraulic resistance of the control element can also be calculated via stored pressure curves or resistance curves. These pressure curves or resistance curves can be measured or calculated in dependence on a measured volumetric flow rate and/or a, possibly also percentage, degree of opening of a control element.

Because the hydraulic resistance of a control element and the volumetric flow rate within a temperature control line and/or a temperature control circuit are known, the pressure drop caused by the degree of opening of the control element can be calculated for each degree of opening.

Because the pressure drop of the control element and the total pressure drop of a temperature control line are known, the still unknown pressure drop of the temperature control channel through a mold can thus be calculated. This pressure drop can relate only to the temperature control channel, but can also include other contributions such as tubing, couplings, several temperature control channels or the like. From the pressure drop, the hydraulic resistance thereof can be calculated.

In this way, the hydraulic resistance of each temperature control channel in a temperature control line to be monitored and to be controlled or to be regulated can be calculated at any time and with any degree of opening of the control element in control mode or regulating mode.

Both current and stored hydraulic resistances and/or changes in resistance can be output and made available to the operating staff.

It can be provided to ascertain an actual status and/or a reference status of temperature control channels before the production with a molding tool.

It can be provided to ascertain an actual status and/or a reference status of temperature control channels after the production with a molding tool.

Ascertaining an actual status and/or a reference status of temperature control channels can be used, for example, to detect alterations in the temperature control channels which come about through operation and/or through storage.

It can be provided to ascertain an actual status and/or a reference status of temperature control channels in the like-new state of the molding tool.

Instead of or in addition to ascertaining an actual status and/or a reference status of temperature control channels, a transmission of the actual status and/or the reference status of temperature control channels can take place, wherein the transmission takes place electrically and/or electronically, preferably by dataset and/or cloud.

The status of the mold and/or the temperature control channels can be made accessible to the operating staff through pressure drops and/or through hydraulic resistances via an output element, preferably a visual display device. These values can be made accessible to the operating staff acoustically and/or visually.

Hydraulic resistances represent status parameters and process parameters that can be easily interpreted. An optimally plannable and constantly status-based servicing of molding tools and machines can thus be made possible.

It can also be provided that pressure drops, volumetric flow rates and/or hydraulic resistances are made accessible as absolute values, comparative values and/or relative values.

In another embodiment it can be provided that pressure drops and/or hydraulic resistances are indicated as percentages. In such an embodiment, an actual status of a hydraulic resistance of a temperature control line in combination with the reference status thereof and/or target status of the hydraulic resistance of the temperature control line can yield a percentage and be output as such. In this embodiment, a relative value of 100% can correspond to a volumetric flow rate according to the reference status and/or the target status, a relative value below 100% can correspond to a partial blockage, a relative value of 0% can correspond to a complete blockage and a relative value above 100% can correspond to too low an actual status of a hydraulic resistance of a temperature control line, for example due to a torn or burst hose. Relative values for pressure drops and/or hydraulic resistances represent values that can be easily understood.

In another embodiment it can be provided that measured values for the pressure differences and the volumetric flow rates and/or correlating quantities are ascertained for the at least one temperature control line, these measured values are juxtaposed with each other and, through a comparison with each other, represent comparative values or lead to comparative values which reflect hydraulic resistances and/or changes in hydraulic resistance with regard to the respective degree of opening of the at least one control element. In this embodiment, a temperature control line can be compared with itself over a particular time period and/or a section of a temperature control line can be compared with another section of the same temperature control line and/or a temperature control line can be compared with another temperature control line.

In a particularly preferred embodiment it can be provided that measured values for the pressure differences and the volumetric flow rates and/or correlating quantities are ascertained for the at least one temperature control line, wherein these quantities represent real numbers, preferably rational numbers, and can be juxtaposed with each other, preferably in a table and/or a matrix, possibly in a comparative manner.

Changes in the values can also be made accessible to the operating staff in order to be able to react in a timely manner in the case of a deterioration of the temperature control lines. If the change lies at or above a defined threshold value, for example R_{TC} factor, an alarm, production stop or the like can be triggered on the machine and/or a notification of an impending service can be issued.

If changes should be measured during a reclamping of a mold, the operating staff can have the option of setting these changed parameters as a new reference status. This makes sense above all when the hydraulic resistances have become lower in the course of servicing.

Checking changed parameters, ascertaining an actual status or reference status, setting changed parameters as a new reference can either be effected automatically by the device or manually by the operating staff.

Through the monitoring of temperature control lines and the simultaneous control and/or regulation of the control elements present in the temperature control lines it is possible to check whether the temperature control circuits have been correctly connected to the distributor circuit in comparison with a reference.

The reference can originate from previous measurements, from a parts dataset for the mold or from a dataset for a structurally identical mold.

Alternatively or additionally, this reference can also originate from simulation data and/or CAD models of the mold.

An assignment could thus be effected in which, for example, the connected temperature control channels can be assigned to corresponding temperature control channels in a CAD model and the measured hydraulic resistances can be compared with the calculated hydraulic resistances. This can be carried out for all temperature control channels present or also only for some of them.

Through an assignment of measured temperature control channels to calculated ones and a comparison of calculated and measured parameters, status tables which comprise values such as volumetric flow rate, temperature, pressure, hydraulic resistances and/or the like as well as changes in these values can be created and can be assigned to the correct temperature control channel, the correct temperature control circuit and/or the correct temperature control line.

If, for example, a hydraulic resistance of a temperature control channel does not correspond to the reference with a defined permitted deviation, the control device can output a warning message, an alarm or a notification. For example, in the case of a tubing error, a temperature control circuit could be connected to an incorrect distributor circuit.

The notification can be transmitted to a superordinate level.

The notification can be used in order to discover that temperature control circuits have been transposed during connection.

It is conceivable that, through comparison with the reference and an independent discovery of an error, for example a tubing error, the set values can be automatically transposed by the data processing unit such that the correct assignment and control or regulation is available to the operating staff during operation and on the output element, preferably the visual display device.

A further option for utilizing the calculations of temperature control lines from effective process parameters lies in ascertaining the best possible tubing configuration. Thus, it may make sense, for example, to collect similar temperature control circuits on the same regulated temperature control media distributor. Through the calculation of individual hydraulic resistances and/or changes in hydraulic resistances, it may be possible to generate a recommendation as to how the temperature control circuits are to be interconnected so that the resulting total hydraulic resistance of a temperature control line with temperature control circuits connected in series is sufficiently low.

When there are so many temperature control lines and/or temperature control circuits that they cannot all be connected to the connectors of the temperature control media distributor, several temperature control lines and/or temperature control circuits must be connected together in series. If the temperature control lines and/or temperature control circuits which already have high hydraulic resistances are connected in series, then the total resistance of these temperature control lines and/or temperature control circuits that are connected in series rises in a disadvantageous manner and too little temperature control medium to meet the requirements flows over these temperature control lines and/or temperature control circuits that are connected in series. It is therefore advisable to connect the temperature control lines and/or temperature control circuits which have a comparatively lower hydraulic resistance in series and, as far as possible, not to connect the temperature control lines and/or temperature control circuits with a high resistance in series. A decision as to which temperature control lines and/or temperature control circuits are connected in series can be effected on the basis of the hydraulic resistances from measurements or datasets such as CAD datasets and/or simulation datasets. The relevance of the temperature control circuit to the quality of the component part can also be included in the decision.

Depending on the structural design as well as any combinations of different regulated temperature control media distributors, the measured pressure drops and/or the measured volumetric flow rates within a distributor circuit and/or the measured parameters of several distributor circuits can also be included in the calculations.

Measured or calculated parameters of a mold, such as for example degrees of opening of control elements or hydraulic resistances of temperature control channels, can be made available not just to one machine but to several machines via a data connection, such as for example a cloud. Storage in a dataset is also possible.

A discovery of hose ruptures or leakages when the hydraulic resistance drops suddenly and unexpectedly sharply is also conceivable.

The present invention is not restricted to the disclosed embodiment variants. In an embodiment with two or more temperature control lines, for example, any desired mixed forms of the arrangements of the measuring elements and/or control elements disclosed here can be implemented, thus for example one pressure sensor in each temperature control line and one pressure sensor in the feed line or return line. In the case of another embodiment with one or more temperature control lines, the mold can also be passed through several times. Several component parts can also be used in each temperature control line, for example several measuring elements and/or control elements of a wide variety of types and designs.

Any conceivable combination of component parts and lines which permits a measurement of a pressure drop in at least one temperature control line is possible, wherein this measured pressure drop with a measured volumetric flow rate allows at least one hydraulic resistance and/or one change in resistance to be calculated, wherein the degree of opening of a control element is taken into consideration through the hydraulic resistance.

It is conceivable that different types and structural shapes of control elements are used within the temperature control media supply unit. Thus, for example, different valves, which are desired or necessary in particular temperature control circuits because of their manufacturing tolerances or due to different structural shapes, can be used. It is therefore also possible to use motor-actuated and/or manually actuated control elements, wherein a monitoring of the degree of opening is possible using the control device and/or through manual reading-off with reference to a scale. In order to guarantee monitoring, a calculation or retrieval of a hydraulic resistance in dependence on the degree of opening of the control element is to be provided in the case of all control elements to be used.

The method for monitoring a device of a temperature control media supply system is also applicable to other machine components through which media flow and in which at least one temperature control line is equipped in each case with one measuring element and one control element, for example in control cabinet cooling systems, oil coolers, tie bars, drive train cooling systems, cooling systems of regulators or other electrical and electronic component parts of a molding machine.

What has been stated previously regarding the functioning of the first aspect of the invention can be transferred analogously to the second aspect of the invention, which is why it is primarily the differences of the second aspect that are described below.

In order to describe the functioning of the second aspect of the invention below it is assumed that the temperature change and the volumetric flow rate of at least one temperature control line are measured by two temperature sensors and a further measuring element in this line.

It is conceivable that the temperature change is measured by a temperature sensor in the central feed line and a temperature sensor in each temperature control line that is actually to be monitored. This specific embodiment arrangement of the temperature sensors is not to be understood as limitative.

The measuring element for measuring the volumetric flow rate can be provided directly in the temperature control line to be monitored, in particular the temperature control circuit to be monitored.

The temperature change of the temperature control medium measured by the temperature sensors and the volumetric flow rate measured by the measuring element can be used to calculate the heat flow. The heat flow can be calculated using the following formula:

$${Q}_{T M} = {\dot{m}}_{T M} \cdot {c}_{T M} \cdot ΔT = {Φ}_{T M} \cdot {ρ}_{T M} \cdot {c}_{T M} \cdot ΔT$$

$$Δ T = {T}_{u p} - {T}_{d o w n}$$

The definitions are as follows:
Q_{TM} the at least one heat flow of the temperature control medium in the at least one temperature control line to be monitored,
\dot{m}_{TM} the at least one mass flow of the temperature control medium in the at least one temperature control line to be monitored,
c_{TM} the specific heat capacity of the temperature control medium, wherein the specific heat capacity can be viewed as approximately constant in the case of a substantially constant temperature,
ΔT the temperature change between the temperature sensors,
Φ_{TM} the at least one volumetric flow rate of the temperature control medium in the at least one temperature control line to be monitored,
ρ_{TM} the density of the temperature control medium, wherein the density can be viewed as approximately constant in the case of a substantially constant temperature,
Tᵤₚ the temperature of the temperature control medium in the case of the temperature sensor connected upstream in terms of flow technology and
T_{down} the temperature of the temperature control medium in the case of the temperature sensor connected downstream in terms of flow technology.

The material-specific quantities of the density and heat capacity of the temperature control medium can be viewed either as constant and thus as temperature independent or as variable and temperature dependent. In the case of temperature-dependent densities and/or heat capacities, corresponding tabular values can be input manually and/or retrieved from a memory.

Instead of the heat flow, a quantity derived therefrom can also be used for the monitoring. For example, in the case of a substantially constant density and specific heat capacity of the temperature control medium, a quantity derived from the heat flow, which is calculated solely from the mathematical product of the volumetric flow rate and the temperature change, can be used. This example is not to be understood as limitative. Any derived quantity which is linked to the heat flow can be used.

The temperature change can be either positive or negative.

In the case of a positive temperature change, the temperature measured by the temperature sensor connected upstream in terms of flow technology is higher than the temperature measured by the temperature sensor connected downstream in terms of flow technology. This means that the temperature control medium has a heating function and is itself cooled thereby.

In the case of a negative temperature change, the temperature measured by the temperature sensor connected upstream in terms of flow technology is lower than the temperature measured by the temperature sensor connected downstream in terms of flow technology. This means that the temperature control medium has a cooling function and is itself heated thereby.

The heat flow can be calculated during ongoing operation and compared with a reference value, wherein the reference value was measured for example at the start of the ongoing operation and/or after the installation of a new or recently serviced mold. The reference value can be a preset reference value, which can be retrieved from a memory or from a simulation. The generation of a reference value is not limited to the embodiments mentioned.

If deposits, which form an insulation layer in the temperature control lines, result during operation, this can lead to a reduced exchange of heat between the mold and the temperature control medium and, associated with this, to an alteration of the temperature of the mold. An increased energy requirement for heating the mold can thus become necessary.

It can also be provided that the heat flow for heating up and/or for cooling down a mold is calculated.

A deviation can be calculated by comparing the heat flow with a reference. This deviation can also be an averaging of the heat flow over the duration of a molding cycle.

The advantage of the second aspect of the invention is that, in the case of some deposits and/or blockages, only a slight change in the hydraulic resistance can be observed, whereas the change in the heat flow removed can be more strongly pronounced and thus more easily observable.

The term temperature control line is used for a connection between a feed line and a return line of a temperature control media supply unit. A temperature control line thus contains all technical component parts, connected one after the other in series, between a feed line and a return line. If there is a parallel arrangement, two or more temperature control lines can share sections in the course of the two or more temperature control lines. For example, an initial line section after the feed line can belong to both a temperature control line 1 and a temperature control line 2, up to the point where the initial line section of the two temperature control lines reaches a dividing point.

A temperature control circuit describes only that section of a temperature control line which, if there is a parallel arrangement, runs either:
from the point at which a temperature control line divides into at least two sections up to the point where the at least two sections merge or from the point at which a temperature control line divides into at least two sections up to the point where the at least two sections discharge into one or more return lines or,
starting from one or more feed lines up to the point where at least two sections of at least two temperature control lines merge.

As a rule, a temperature control circuit thus contains a mold component to be temperature controlled, corresponding tubing, couplings and/or other supply devices, sensors as are usual for pressure, volumetric flow rate and temperature, control elements and/or regulating elements and the like. The named constituents of a temperature control circuit are consequently also constituents of a temperature control line, wherein the number and combination of the component parts used in a temperature control line and/or a temperature control circuit are not limited or prescribed in any way by the above-mentioned examples.

A temperature control channel is merely that section of a temperature control line which runs through a molding tool.

A temperature control media supply unit must thus consist of at least one temperature control line. It makes sense for this one temperature control line to contain at least one temperature control channel. When a parallel arrangement is used, several temperature control circuits can be installed, which, as makes sense, each contain one temperature control channel.

By a volumetric flow rate measuring element can also be meant a flow sensor.

By a volumetric flow valve can also be meant a flow regulator or a flow regulating valve.

Further advantageous embodiments of the invention are defined in the dependent claims.

In a preferred embodiment it can be provided that, through the measurement of the at least one pressure drop, the sum of the pressure drops of at least two hydraulic resistance contributions, in particular of at least one consumer component of the molding machine, preferably of a temperature control channel through the mold, of a control cabinet cooling system, of a heat exchanger for an oil cooler, of a tie bar cooling system or of a heat exchanger for a drive train, as well as of at least one control element, is measured and/or calculated, wherein one hydraulic resistance contribution of the at least two hydraulic resistance contributions represents the at least one control element.

This means that a measured pressure drop can result from at least two hydraulic resistance contributions, namely through at least one temperature control channel through a mold and through at least one control element, wherein an unlimited number of temperature control lines may be possible, implemented in a parallel arrangement.

In a preferred embodiment it can be provided that the at least one pressure drop is measured by in each case one pressure sensor in the feed line and one pressure sensor in the return line and/or the at least one temperature change is measured by in each case one temperature sensor in the feed line and one temperature sensor in the return line.

This saves production costs since, even in the case of several temperature control lines which can be implemented as a parallel arrangement, only two pressure sensors, one each in the feed line and in the return line, are necessary. It is assumed here that the pressure drop over all circuits arranged in parallel remains approximately the same size.

If, due to the overall size of the device of the temperature control media supply system, further pressures and/or pressure drops are also to be measured in addition to the at least one pressure drop of a temperature control line, as many further pressure sensors as desired can be provided. The number, the design and/or the position of the additionally provided pressure sensors within the device of the temperature control media supply system can be freely chosen.

It can be provided that more than one pressure drop is measured for each desired temperature control circuit and/or each desired temperature control line. An individual pressure drop in a temperature control circuit and/or a temperature control line can thus be taken into consideration for calculating a hydraulic resistance of this temperature control circuit and/or this temperature control line. This can make sense for example when increased accuracy is necessary.

In a preferred embodiment it can be provided that the at least one pressure drop is measured by in each case two pressure sensors arranged in series in terms of flow technology in the at least one temperature control line and/or the at least one temperature change is measured by in each case two temperature sensors arranged in series in terms of flow technology in the at least one temperature control line.

In a preferred embodiment it can be provided that the at least one hydraulic resistance and/or the at least one change in resistance of at least one temperature control line to be monitored and to be regulated or to be controlled is calculated from at least two contributions, in particular at least one temperature control channel through a mold and at least one control element.

In a preferred embodiment it can be provided that the at least one hydraulic resistance and/or the at least one change in resistance and/or the at least one heat flow and/or the at least one change in heat flow is presented by an output element, preferably a visual display device, in particular on a screen.

In a preferred embodiment it can be provided that at least one permitted range is defined for the at least one hydraulic resistance and/or for the at least one heat flow of the at least one temperature control line and/or at least one permitted range of change is defined for the at least one change in resistance and/or for the at least one change in heat flow of the at least one temperature control line, and a warning signal is output when the at least one hydraulic resistance and/or the at least one heat flow departs from the at least one permitted range and/or when the at least one change in resistance and/or the at least one change in heat flow departs from the at least one permitted range of change.

In a preferred embodiment it can be provided that the warning signal is output visually, in particular through presentation on a screen, and/or that the warning signal is output acoustically.

In a preferred embodiment it can be provided that the molding machine is switched off when the warning signal is output.

It can be provided that a service command for the mold is output and/or an item of information on a service to be planned is made available in a superordinate production planning platform or level when the at least one hydraulic resistance departs from the at least one permitted range and/or when the at least one change in resistance departs from the at least one permitted range of change.

The availability of a mold for production can be affected by a service command and/or an item of information on a service to be planned.

Since the hydraulic resistance and/or the change therein represent characteristic values that are easy for the operating staff to interpret, they can be presented by an acoustic signal and/or visually on a screen or the like. There is also the possibility to make such signals available to the whole production environment and/or machine park across all machines if a corresponding connection exists between individual machines (LAN, for example via ethernet, or also wirelessly). The size of such a network can assume any desired scale, thus also exist between different machine parks at different sites. Such a network can also be utilized for central monitoring, control and/or regulation.

In a preferred embodiment it can be provided that, for determining the at least one permitted range and/or the at least one permitted range of change before, during and/or after operation, a calculation of the at least one hydraulic resistance (R) and/or of the at least one heat flow (Q) is carried out using measured data and/or using data from a simulation and/or using design data, in particular CAD data.

In order to be able to determine the permitted ranges and/or the permitted target values of the hydraulic resistances and/or changes in resistance, a measurement of reference values of the hydraulic resistances and/or changes in resistance can be carried out on the machine.

It can be provided that the permitted ranges and/or the permitted target values of the hydraulic resistances and/or changes in resistance are set by an operator through a freely choosable specification and/or a preallocated specification.

In a preferred embodiment it can be provided that the at least one hydraulic resistance (R) and/or the at least one change in resistance and/or the at least one heat flow (Q) and/or the at least one change in heat flow is calculated by the consumer component of the molding machine at least once using measured data and is calculated at least once using data from a simulation or using design data, in particular CAD data, wherein the at least two calculated values of the at least one hydraulic resistance (R) and/or of the at least one change in resistance and/or of the at least one heat flow (Q) and/or of the at least one change in heat flow are reconciled in order to discover a deviation or agreement.

In the case of such an embodiment, the new status of a mold can be derived and/or tubing errors can be discovered through the reconciliation of a measured hydraulic resistance with simulation or CAD data.

In a preferred embodiment it can be provided that the reconciliation of the at least two calculated values of the at least one hydraulic resistance (R) and/or the at least one change in resistance takes temperatures and/or temperature differences into consideration.

In a preferred embodiment it can be provided that a tubing proposal is created on the basis of absolute values, comparative values, relative values and/or one or more sequences according to size of the hydraulic resistances and/or changes in hydraulic resistance and/or of the heat flows and/or changes in heat flow of the consumer components, wherein consumer components with lower hydraulic resistances and/or low heat flows are connected in series.

In a preferred embodiment it can be provided that the tubing proposal is created and/or adapted taking into consideration the measured and/or predetermined temperatures and/or temperature differences of the consumer components.

If temperatures and/or temperature differences are available from data of a simulation or from design data, they can be included in a tubing proposal for a series/parallel arrangement of the consumer components and/or reconciled with the measured values. For example, a very small temperature difference of a consumer component can be obtained in a simulation and a very large temperature difference can be obtained in the measurement, although hydraulically there is no abnormality. Through this reconciliation, deposits or thermal insulation layers present in the temperature control lines can be discovered.

Such measurements and simulations can also be carried out directly before the start of operation. They can furthermore be carried out at regular intervals. The development of the hydraulic resistances and/or changes in resistance as well as their permitted ranges and target values can be documented in this way in order to achieve an even better status-based planning of device servicing.

For comparable or identical machines or comparable machine settings, stored data can thus be used, and it is possible to economize on measurements and simulations to a self-chosen extent.

In a preferred embodiment it can be provided that the at least one hydraulic resistance Rᵢ of the at least one temperature control line i to be monitored and to be regulated or to be controlled is calculated according to the equations

$${R}_{i} = \frac{Δ p ( δ )}{{Φ}_{i}^{n}}$$

$$Δ p ( δ ) = Δ {p}_{2 i} + Δ {p ( δ )}_{7 i}$$

The definitions are as follows:
Rᵢ the at least one hydraulic resistance in the at least one temperature control line i to be monitored and to be regulated or to be controlled
Δp(δ) the at least one pressure drop of the supply system with the at least one temperature control line to be monitored and to be regulated or to be controlled in dependence on the degree of opening δ of the at least one control element
Φᵢ the at least one volumetric flow rate in the at least one temperature control line i to be monitored and to be regulated or to be controlled
n a dimensionless characteristic value in dependence on various parameters such as for example the cross section through which the volumetric flow Φᵢ flows and/or the flow conditions, wherein the characteristic value n is approximately 2 in the case of a circular cross section and ideal flow conditions,
Δp₂ᵢ the at least one pressure drop of at least one temperature control channel through a mold in the at least one temperature control line i to be monitored and to be regulated or to be controlled and
Δp(δ)₇ᵢ the at least one pressure drop in dependence on the degree of opening δ of the at least one control element in the at least one temperature control line i to be monitored and to be regulated or to be controlled

In a preferred embodiment it can be provided that the at least one hydraulic resistance Rai of the at least one mold in the at least one temperature control line i to be monitored and to be regulated or to be controlled is calculated according to the equations

$$Δ {p ( δ )}_{7 i} = {R ( δ )}_{7 i} \cdot {Φ}_{i}^{n}$$

$$Δ {p}_{2 i} = Δ p ( δ ) - Δ {p ( δ )}_{7 i}$$

$${R}_{2 i} = \frac{Δ {p}_{2 i}}{{Φ}_{i}^{n}}$$

The definitions are as follows:
Δp(δ)₇ᵢ the at least one pressure drop in dependence on the degree of opening δ of the at least one control element in the at least one temperature control line i to be monitored and to be regulated or to be controlled
R(δ)₇ᵢ the at least one hydraulic resistance of the at least one control element in dependence on the degree of opening (δ) of the at least one control element in the at least one temperature control line i to be monitored and to be regulated or to be controlled
Φᵢ the at least one volumetric flow rate in the at least one temperature control line i to be monitored and to be regulated or to be controlled
n a dimensionless characteristic value in dependence on various parameters such as for example the cross section through which the volumetric flow Φᵢ flows and/or the flow conditions, wherein the characteristic value n is approximately 2 in the case of a circular cross section and ideal flow conditions,
Δp₂ᵢ the at least one pressure drop of at least one temperature control channel through a mold in the at least one temperature control line i to be monitored and to be regulated or to be controlled
Δp(δ) the at least one pressure drop of the supply system with the at least one temperature control line to be monitored and to be regulated or to be controlled in dependence on the degree of opening δ of the at least one control element and
R₂ᵢ the at least one hydraulic resistance of a temperature control channel through a mold in the at least one temperature control line i to be monitored and to be regulated or to be controlled

In a preferred embodiment it can be provided that the at least one hydraulic resistance R(δ)₇ᵢ of the at least one control element in dependence on the degree of opening (δ) of the at least one control element in the at least one temperature control line i to be monitored and to be regulated or to be controlled is read from a computer-readable storage medium and/or calculated by a processor using an approximation function.

In a preferred embodiment it can be provided that a temperature of the temperature control medium is measured and the temperature of the temperature control medium is included in the calculation of the at least one hydraulic resistance R.

A measured temperature difference between feed line and return line of a temperature control line and/or within a temperature control circuit can also be used as optimization criterion, for example. When several temperature control circuits are present, taking at least one temperature and/or at least one temperature difference into consideration can be useful in order to plan tubing systems for temperature control circuits connected in series that make sense.

An embodiment for this can contain four temperature control circuits. Two circuits have a high hydraulic resistance but small temperature difference. Two further circuits have a high hydraulic resistance but a larger temperature difference. Because the circuits are connected in series, the hydraulic resistance increases and the volumetric flow rate falls, as a result of which the temperature difference increases. However, in the first two circuits the temperature difference can still be in the desired range. It would thus be preferred to connect those circuits in series which thereafter still have a temperature difference within the permitted range.

During the measurement of the temperature, at least one temperature sensor can be provided in a temperature control line to be monitored. Such a temperature sensor can be connected to the data processing unit. It is also conceivable to take further quantities, such as the Reynolds number, the viscosity and/or the compressibility of the temperature control medium, into consideration. Furthermore, such temperature-corrected data can be made available on the computer-readable storage medium.

In a preferred embodiment, water is used as temperature control medium.

Because of its high heat capacity, in many cases water is well suited as temperature control medium. Other media or water with additives can naturally also be used.

In a preferred embodiment of a method for supplying temperature control media to a mold of a molding machine, wherein at least one control element, in particular a volumetric flow valve, is regulated or controlled according to a target value for a pressure of the temperature control medium and/or for a volumetric flow rate of the temperature control medium, the target value is calculated in dependence on the at least one hydraulic resistance R₂ᵢ and/or the at least one change in resistance ΔR₂ᵢ of a temperature control channel through a mold in the at least one temperature control line i to be monitored and to be regulated or to be controlled.

In a further embodiment of the invention, the control element can be regulated or controlled on the basis of a target value. This target value can be calculated from the at least one hydraulic resistance R₂ᵢ and/or a change in resistance ΔR₂ᵢ of a temperature control channel through a mold of a temperature control line i. In addition to a control and/or regulating unit of the control element necessary for this, a data processing unit can be used, which can be connected to the at least one control element and the at least one measuring element.

Protection is also sought for a device for supplying temperature control media to a mold of a molding machine with:
a feed line for the central supply of a temperature control medium,
a return line for the central removal of the temperature control medium,
at least one temperature control line, which is connected to the feed line and the return line, for controlling the temperature of the mold,
at least one measuring element, in particular a volumetric flow rate measuring element, in each of the temperature control lines actually to be monitored for measuring at least one volumetric flow rate,
at least one control element, in particular a volumetric flow valve, in each of the temperature control lines to be regulated or to be controlled for regulating or controlling a volumetric flow rate, and
data processing unit, which is connected to the at least one control element and the at least one measuring element, wherein
at least two pressure sensors are provided, which are connected to the data processing unit, for measuring at least one pressure drop,
at least one hydraulic resistance and/or at least one change in resistance of the at least one temperature control line can be calculated by the data processing unit on the basis of the at least one measured volumetric flow rate and on the basis of the at least one measured pressure drop,
the degree of opening of the at least one control element is taken into consideration in the calculation of the at least one hydraulic resistance and/or the at least one change in resistance, and
the at least one hydraulic resistance and/or the at least one change in resistance can be presented by an output element, preferably a visual display device.

Protection is also sought for a device for supplying temperature control media to a mold of a molding machine with:
a feed line for the central supply of a temperature control medium,
a return line for the central removal of the temperature control medium,
at least one temperature control line, which is connected to the feed line and the return line, for controlling the temperature of the mold,
at least one measuring element, in particular at least one volumetric flow rate measuring element, in each of the temperature control lines actually to be monitored for measuring at least one volumetric flow rate,
data processing unit, which is connected to the at least one control element and the at least one measuring element, wherein
at least two temperature sensors are provided, which are connected to the data processing unit, for measuring at least one temperature change,
at least one heat flow (Q) and/or at least one change in heat flow of the at least one temperature control line can be calculated by the data processing unit on the basis of the at least one measured volumetric flow rate and on the basis of the at least one measured temperature change, and
the at least one heat flow (Q) and/or the at least one change in heat flow can be presented by an output element, preferably a visual display device.

In a preferred embodiment, at least one consumer component of the molding machine, preferably a temperature control channel through the mold, a control cabinet cooling system, a heat exchanger for an oil cooler, a tie bar cooling system or a heat exchanger for a drive train, as well as at least one control element are arranged in series one after the other between at least two pressure sensors.

In a preferred embodiment of a device for data processing, at least one hydraulic resistance and/or at least one change in resistance is calculated using the at least one measured pressure drop and the regulated or controlled degree of opening of the at least one control element.

In a preferred embodiment of a device, a temperature sensor, connected to the data processing unit, is provided for measuring a temperature of the temperature control medium and that the at least one hydraulic resistance can be calculated on the basis of the temperature.

In a preferred embodiment of a device, at least one permitted range for the at least one hydraulic resistance and/or for the at least one heat flow and/or at least one permitted range of change for the at least one change in resistance and/or for the at least one change in heat flow of the at least one temperature control line can be stored in the data processing unit and that a warning signal can be output when the at least one hydraulic resistance and/or the at least one heat flow departs from the at least one permitted range and/or when the at least one change in resistance and/or the at least one change in heat flow departs from the at least one range of change.

In a preferred embodiment, a data processing unit is available in which at least one permitted range for the at least one hydraulic resistance and/or at least one permitted range of change for the at least one change in resistance of the at least one temperature control line can be stored. A warning signal can be output by this data processing unit when the at least one hydraulic resistance departs from the at least one permitted range and/or when the at least one change in resistance departs from the at least one range of change.

Protection is also sought for a computer program product for carrying out a method according to the invention.

Protection is also sought for a computer-readable storage medium for carrying out a method according to the invention.

Protection is also sought for a computer-readable data carrier for carrying out a method according to the invention.

Protection is also sought for a data carrier signal for carrying out a method according to the invention.

Protection is also sought for a molding machine which can carry out a method according to the invention.

By molding machines can be meant injection-molding machines, transfer molding machines, presses and the like. Molding machines in which the plasticized material is supplied to an open mold are also entirely conceivable.

### BRIEF DESCRIPTION OF THE DRAWINGS

Further advantages and details of the invention are revealed by the figures and the associated description of the figures, in which:

FIG. 1 schematically shows an embodiment of a temperature control media supply unit with two temperature control lines connected in parallel;

FIG. 2 is a further schematic depiction of an embodiment of a temperature control media supply unit with one temperature control line;

FIG. 3 is a further schematic depiction of an embodiment of a temperature control media supply unit with two temperature control lines connected in parallel, two pressure sensors at the start of each temperature control circuit and one pressure sensor in the return line;

FIG. 4 is a further schematic depiction of an embodiment of a temperature control media supply unit, similar to the embodiment from FIG. 3;

FIG. 5 is a further schematic depiction of an embodiment of a temperature control media supply unit, similar to the embodiments from FIG. 3 and FIG. 4;

FIG. 6 is a further schematic depiction of an embodiment of a temperature control media supply unit with two temperature control lines connected in parallel and in each case two pressure sensors at the start and at the end of each temperature control circuit;

FIG. 7 is a further schematic depiction of an embodiment of a temperature control media supply unit with two temperature control lines connected in parallel, one pressure sensor in the feed line and two pressure sensors at the end of each temperature control circuit;

FIG. 7b is a further schematic depiction of an embodiment of a temperature control media supply unit with two temperature control lines connected in parallel, one temperature sensor in the feed line and in each case one temperature sensor at the end of the respective temperature control circuit;

FIG. 8 is a further schematic depiction of an embodiment of a temperature control media supply unit with hydraulic graphical symbols and with three temperature control lines connected in parallel;

FIG. 9 shows a relationship between the pressure drop in bar and the volumetric flow rate in l/min in dependence on the degree of opening of a specific control element;

FIG. 10 shows approximation function for determining a hydraulic resistance with the aid of a coefficient in dependence on the percentage valve position of a control element;

FIG. 11: is a block diagram of an embodiment of a method according to the first aspect of the invention;

FIG. 12: is a block diagram of an embodiment of a method according to the second aspect of the invention.

### DETAILED DESCRIPTION OF THE INVENTION

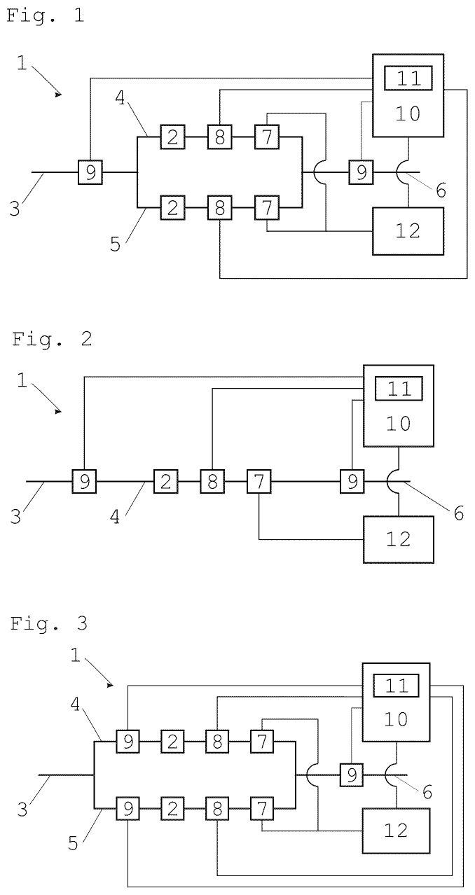

FIG. 1 shows a temperature control supply unit 1 for controlling the temperature of two temperature control channels of a mold, in particular a mold of a molding machine, in particular an injection-molding machine. The feed line 3 of the temperature control medium is shown on the left-hand side in FIG. 1. The feed line 3 is the central supply line for the entire temperature control supply unit.

The return line 6 can be seen on the right-hand side. This return line 6 serves for draining the temperature control medium.

In principle, several feed lines or return lines could also be included, but the measurement of a pressure drop for each temperature control line to be monitored between feed lines and return lines must be guaranteed. This pressure drop is measured using the pressure sensors 9, of which preferably in each case one is located in the feed line 3 and one in the return line 6. In this way, a pressure drop can be measured for both temperature control circuits in the case of a parallel arrangement of two temperature control lines or temperature control circuits 4, 5. As this is a parallel arrangement of the individual circuits, the pressure drop in the individual circuits is approximately constant.

As can be seen in FIG. 8, a parallel arrangement is not limited to two temperature control lines but can contain as many temperature control lines or temperature control circuits as desired. Each temperature control line to be monitored contains an element to be monitored, as a rule a temperature-controlled mold with temperature control channels 2.

It is conceivable that several such temperature control channels 2 are provided, which run through the same or also through different molds. Thus, several temperature control channels could be taken into consideration within one temperature control line or one temperature control circuit. How comprehensive the monitoring of the individual temperature control channels is thus depends on both the structural design and the number and arrangement of the measuring elements.

In any case one measuring element 8, in particular one volumetric flow rate measuring device, in particular a volumetric flow rate measuring element, is to be provided for each temperature control channel 2 to be monitored. With the two measuring elements 8 in the two temperature control lines 4, 5, two volumetric flow rates Φ₄ and Φ₅ can thus be measured.

Besides the monitoring, a control element 7, in particular a valve, in particular a volumetric flow valve, is also located in each temperature control line to be controlled or to be regulated.

Like the pressure sensors 9, the measuring elements 8, in particular the volumetric flow rate measuring elements, are connected to a data processing unit 10. This data processing unit 10 has an output element 11, preferably a visual display device.

The control elements 7 are connected to a control device 12.

This control device 12 is in turn connected to the data processing unit 10.

In this way, measured values of the pressure sensors 9 and of the measuring elements 8 can be received by the data processing unit 10, evaluated and output via the output element 11, preferably the visual display device. Subsequently, a signal for controlling or regulating the control elements 7 can be transmitted via the control device 12.

Naturally, the control device 12 and the data processing unit 10 are only logically separate units and can be present in a single physical device without problems. In modern molding machines it is the norm that both are integrated in a common machine control system.

FIG. 2 shows a further schematic embodiment of a temperature control media supply unit 1 with only one temperature control line or one temperature control circuit 4 analogously to FIG. 1.

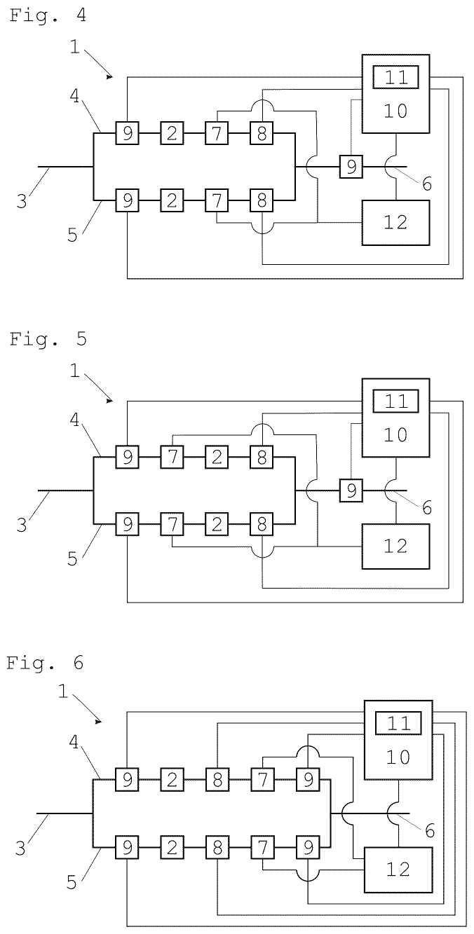

FIG. 3 shows a further schematic embodiment of a temperature control media supply unit 1 with two temperature control lines 4, 5 connected in parallel, two pressure sensors 9 at the start of each temperature control circuit 4, 5 and one pressure sensor 9 in the return line 6. The remaining constituents are analogous to the previous figures.

Due to the central feed line 3 and return line 6, an approximately constant pressure drop in the two temperature control circuits 4, 5 can be assumed. However, should it be desired to measure the pressure drops for each temperature control circuit separately independently of the supply pressure of the temperature control medium from the feed line 3, such an arrangement is recommended. This may be the case, for example, if different feed lines 3 are used.

FIG. 4 shows a further schematic embodiment of a temperature control media supply unit 1, similar to the embodiment from FIG. 3.

In this embodiment, however, the positions of the measuring elements 8 and of the control elements 7 are transposed in contrast to the embodiment from FIG. 3. In other words, in the two temperature control lines 4, 5 shown and connected in parallel, the control elements 7 are connected downstream of the temperature control channels 2 and upstream of the measuring elements 8.

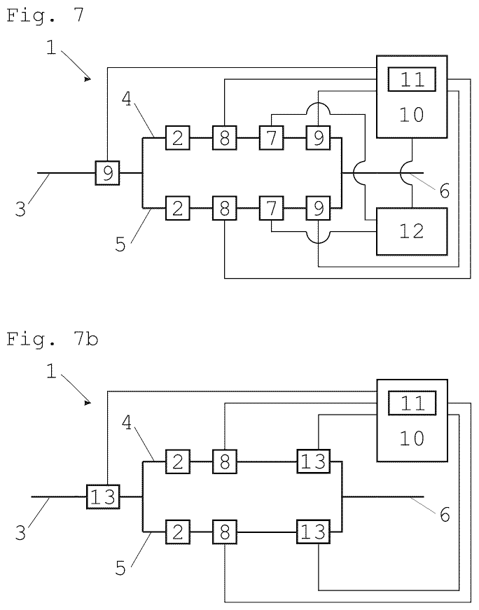

FIG. 5 shows a further schematic embodiment of a temperature control media supply unit 1, similar to the embodiments from FIG. 3 and FIG. 4.

In this embodiment, however, the positions of the temperature control channels 2 and of the control elements 7 are transposed in contrast to the embodiment from FIG. 4. In other words, in the two temperature control lines 4, 5 shown and connected in parallel, the temperature control channels 2 are connected downstream of the control elements 7 and upstream of the measuring elements 8.

FIG. 6 shows a further schematic embodiment of a temperature control media supply unit 1 with two temperature control lines 4, 5 connected in parallel and in each case two pressure sensors 9 at the start and at the end of each temperature control circuit 4, 5. The remaining constituents are analogous to the previous figures.

Due to the central feed line 3 and return line 6, an approximately constant pressure drop in the two temperature control circuits 4, 5 can be assumed. However, should it be desired to measure the pressure drops of individual temperature control circuits completely independently of the supply pressure and of other temperature control circuits, then such an arrangement is recommended. This may be the case, for example, if different feed lines 3, different return lines 6 and/or a greater accuracy are desired.

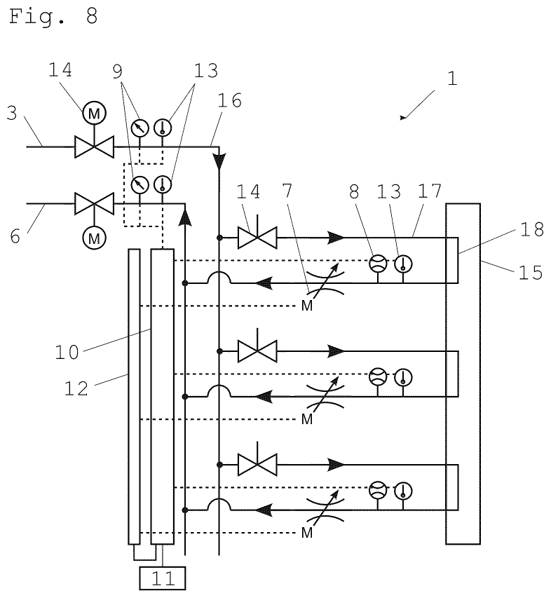

FIG. 7 shows a further schematic embodiment of a temperature control media supply unit 1 with two temperature control lines 4, 5 connected in parallel, two pressure sensors 9 at the end of each temperature control circuit 4, 5 and one pressure sensor 9 in the feed line 3. The remaining constituents are analogous to the previous figures.

Due to the central feed line 3 and return line 6, an approximately constant pressure drop in the two temperature control circuits 4, 5 can be assumed. However, should it be desired to measure the pressure drops of the individual temperature control circuits separately from each other, then such an arrangement is recommended. This may be the case, for example, when the temperature control channels 2 of the temperature control circuits 4, 5 to be monitored and to be controlled or to be regulated have hydraulic resistances that deviate greatly from each other, and a greater accuracy of the pressure measurement is desired. This can come about, for example, due to greatly different geometries of the temperature control channels in the individual temperature control circuits.

FIG. 7b shows a further schematic embodiment of a temperature control media supply unit 1 with two temperature control lines 4, 5 connected in parallel, one temperature sensor 13 in the feed line 3 and in each case one temperature sensor 13 at the end of the respective temperature control circuit 4, 5.

The temperature of the temperature control medium measured in the feed line 3 by the temperature sensor 13 connected upstream in terms of flow technology is made available to the data processing unit 10.

The temperatures of the temperature control medium measured in the temperature control lines 4 and 5 by the temperature sensors 13 connected downstream in terms of flow technology are made available to the data processing unit 10.

Volumetric flow rates can be measured by the measuring elements 8 in the two temperature control lines 4 and 5 and made available to the data processing unit 10.

The temperature changes in the temperature control medium in the temperature control lines 4 and 5, in conjunction with the measured volumetric flow rates in the temperature control lines 4 and 5, can be converted by the data processing unit 10 into heat flows for the two temperature control lines 4 and 5.

The calculated heat flows and/or the changes in the heat flows of the temperature control lines 4 and 5 can be output for the operating staff by the output element 10.

FIG. 8 shows a further schematic embodiment of a temperature control media supply unit 1 with three temperature control circuits 17 connected in parallel.

Here, all hydraulic component parts are represented with graphical symbols. As in the previous figures, one feed line 3 and one return line 6 are shown, which in each case contain a pressure sensor 9, a temperature sensor 13 and a motor-actuated shut-off valve 14.

The temperature control line 16 starts after the motor-actuated shut-off valve 14 and runs as far as a first dividing point, at which the temperature control line is divided into two sections. One of these two sections is the line of a temperature control circuit 17 leading to the mold 15. In this embodiment, this first temperature control circuit 17 is identical in design to two further temperature control circuits. The first temperature control circuit 17 starts with the first dividing point of the temperature control line 16 and ends with the last merging before the return line 6. The first temperature control circuit 17 contains a temperature control channel 18, which runs through the mold 15.

There are three temperature control circuits 17 7 connected in parallel, which each have a manually actuated shut-off valve 14 in the line flowing to the mold 15. In the lines of the individual temperature control circuits 17 flowing away from the mold 15 there are located in each case a restrictor valve 7, a volumetric flow rate measuring device 8 and a temperature sensor 13. The restrictor valve 7 is motor-actuated, connected to the control device 12 and makes it possible to control or to regulate the volumetric flow rate by means of adjustable cross sections. All of the sensors for pressure, temperature and volumetric flow rate of the temperature control media supply unit 1 are connected to the data processing unit 10, which for its part is connected to an output element 11, preferably a visual display device, and the control device 12.

A pressure difference can be measured by the pressure sensors 9 in the feed line 3 and in the return line 6.

The pressure difference can be controlled or regulated by the control elements 7.

The pressure difference can be used to calculate one or more hydraulic resistances and/or one or more changes in hydraulic resistances.

Temperature differences can be measured by the temperature sensor 13 in the feed line 3, in the individual temperature control circuits 17 and/or in the return line 6.

The temperature differences can be controlled or regulated by the control elements 7.

The temperature differences can be used to calculate one or more heat flows and/or one or more changes in heat flows.

As represented in FIG. 8, both aspects of the invention can be implemented in one and the same temperature control media supply system 1. It can be provided here that the monitoring of the temperature control media supply system 1 is effected either using hydraulic resistances and/or changes therein or using heat flows and/or changes therein. However, it can also be provided that the monitoring is effected both using hydraulic resistances and/or changes therein and using heat flows and/or changes therein.

The same can also apply to the control and/or regulation of the temperature control media supply system 1. Thus, it can be provided that the control and/or regulation of the temperature control media supply system 1 is effected in conjunction with hydraulic resistances and/or with changes in resistance and/or with heat flows and/or with changes in heat flow using the available control elements 7, for example.

The embodiment represented in FIG. 8 does not represent a limitation of the claimed invention but is merely intended to represent a specific hydraulic connection diagram, such as can be used in practice. Combinations and mixed forms of all previously named embodiment variants are likewise possible, as is the use of additional and/or different component parts. The number of temperature control lines or temperature control circuits is likewise not limited.

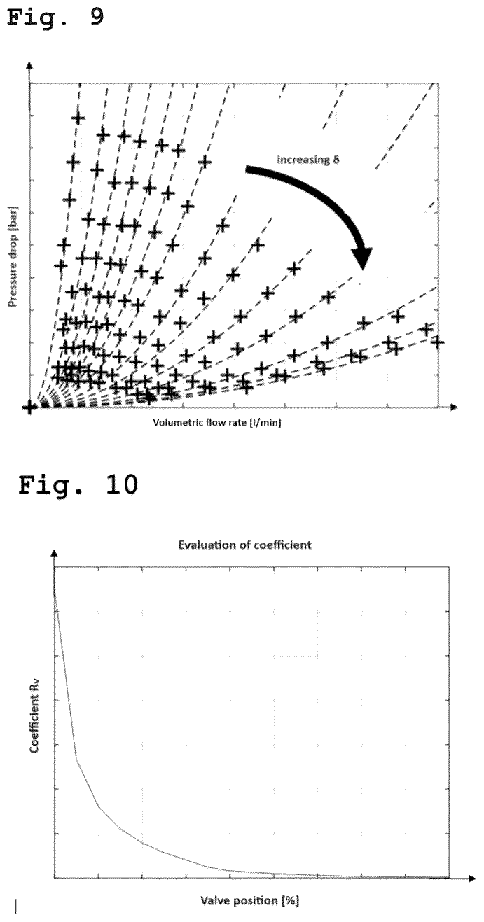

FIG. 9 shows a graph with several curves of pressure drops (y axis), measured in advance and then stored, in dependence on the volumetric flow rate (x axis) and the degree of opening δ of a specific control element 7.

The pressure drops coming about as a result of a particular volumetric flow rate and a particular degree of opening δ can be measured for a particular control element 7, in particular a volumetric flow valve, of defined size, design, etc. These measured points are marked in the graph by crosses.

Curves of the pressure drops in dependence on the volumetric flow rate present can be ascertained at a constant degree of opening δ. These curves are represented by dashed lines in the graph and can substantially be the connection of the pressure drops marked by crosses.

The degree of opening δ increases continuously from the steepest characteristic curve, on the left in the graph, to the flattest characteristic curve, on the right in the graph. The smaller the degree of opening δ of the control element 7 is, i.e. the smaller the cross section of the volumetric flow through the control element 7 is, the greater its hydraulic resistance becomes. The influence of the hydraulic resistance as the volumetric flow rate increases can be seen through a greater pressure drop and thus a steeper characteristic curve.

If the degree of opening δ of the control element 7 and the volumetric flow rate present are known, the pressure drop caused by the control element 7 can be determined, which can be seen using the graph.

Subsequently, the hydraulic resistance can thus also be determined, which is not represented in the graph.

FIG. 10 shows a graphical approximation function for determining a hydraulic resistance of a control element 7, here a valve V.

In the graph, the percentage opening position of the valve V is indicated on the x axis. The y axis renders the hydraulic resistance of the valve V.

If the degree of opening δ of the valve V is known, the pressure drop of the valve V can subsequently be calculated using this approximation function together with a measured volumetric flow rate.

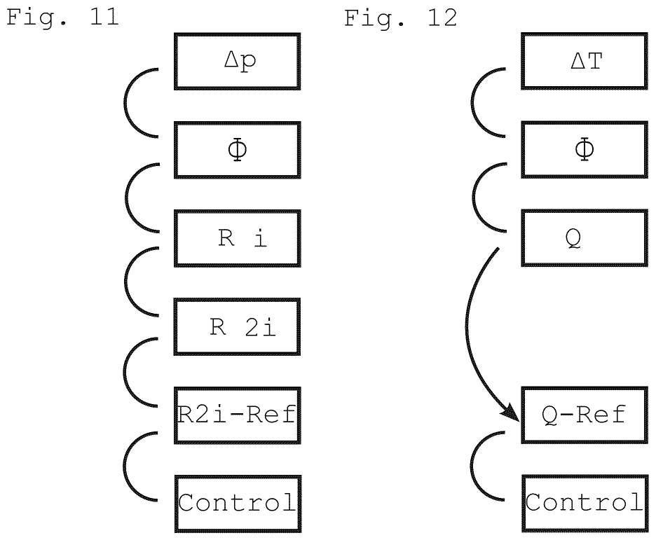

FIG. 11 shows a block diagram of an embodiment of a method according to the first aspect of the invention.

In a method according to the first aspect of the invention, a temperature control media supply system 1 can be monitored and/or controlled or regulated by carrying out the following steps.

First, a pressure difference Δp, in particular a pressure drop Δp, is measured, preferably using two pressure sensors 9. Then, a volumetric flow rate Φ is measured using a measuring element 8. Via a data processing unit 10, a hydraulic resistance Rᵢ of a temperature control line i can be calculated from the pressure drop Δp and the volumetric flow rate Φ. The hydraulic resistance R₂ᵢ of a mold 2 in a temperature control line i can be calculated from the degree of opening of the control element 7 and the hydraulic resistance Rᵢ. Any deviation can be identified through the reconciliation (R₂ᵢ−Ref) of the hydraulic resistance R₂ᵢ of a mold 2 with a reference value Ref.

If, in the course of the method, a deviation of the hydraulic resistance Rei from a reference value Ref is identified, for example a control signal (Control) can be output via an output element 11 and/or a control or regulation step (Control) can be automatically initiated, wherein the degree of opening of the control element 7 can be changed in the course of a control or regulation.

Repetition of the method can be initiated automatically at regular intervals and/or at desired points in time by the staff.

The method sequence according to the first aspect of the invention represented in FIG. 11 is merely one embodiment and serves for the representation of a specific method progression. This embodiment is thus not to be understood as limitative.

FIG. 12 shows a block diagram of an embodiment of a method according to the second aspect of the invention.

First, a temperature difference ΔT is measured, preferably using two temperature sensors 13. Then, a volumetric flow rate Φ is measured using a measuring element 8. Via a data processing unit 10, a heat flow Q for a temperature control line, a temperature control circuit and/or a whole temperature control media supply system 1, can be calculated from the temperature difference ΔT and the volumetric flow rate Φ. Any deviation can be identified through the reconciliation (Q−Ref) of the heat flow Q with a reference value Ref.

If, in the course of the method, a deviation of the heat flow Q from a reference value Ref is identified, for example a control signal (Control) can be output via an output element 11. It can also be provided that a control or regulation step (Control) is automatically initiated, wherein the degree of opening of the control element 7 can be changed in the event of a control or regulation.

Repetition of the method can be initiated automatically at regular intervals and/or at desired points in time by the staff.

The method sequence according to the second aspect of the invention represented in FIG. 12 is merely one embodiment and serves for the representation of a specific method progression. This embodiment is thus not to be understood as limitative.

### LIST OF REFERENCE NUMBERS

1 temperature control media supply unit
2 temperature control circuit through a mold
3 feed line
4 temperature control line or temperature control circuit 4
5 temperature control line or temperature control circuit 5
6 return line
7 control element
8 measuring element
9 pressure sensor
10 data processing unit
11 output element
12 control device
13 temperature sensor
14 shut-off valve, manually actuated and/or motor actuated
15 mold
16 temperature control line
17 temperature control circuit
18 temperature control channel

1. A method for monitoring a device for supplying temperature control media to a mold of a molding machine, wherein the device for supplying temperature control media has a feed line and a return line, between which at least one temperature control line is arranged, wherein at least one measuring element, in particular a volumetric flow rate measuring element, is arranged in each of the temperature control lines actually to be monitored, and at least one control element, in particular a volumetric flow valve, is arranged in each temperature control line to be regulated or to be controlled, wherein:
at least one pressure drop in the at least one temperature control line is measured,
at least one hydraulic resistance and/or at least one change in resistance of the at least one temperature control line is calculated on the basis of an at least one volumetric flow rate measured using the at least one measuring element and on the basis of the at least one measured pressure drop, and
the degree of opening of the at least one control element is taken into consideration in the calculation of the at least one hydraulic resistance and/or the at least one change in resistance.

2. A method for monitoring a device for supplying temperature control media to a mold of a molding machine, wherein the device for supplying temperature control media has a feed line and a return line, between which at least one temperature control line is arranged, wherein at least one measuring element, in particular a volumetric flow rate measuring element, is arranged in each of the temperature control lines actually to be monitored, wherein:
at least one temperature change in the at least one temperature control line is measured, and
at least one heat flow and/or at least one change in heat flow of the at least one temperature control line is calculated on the basis of an at least one volumetric flow rate measured using the at least one measuring element and on the basis of the at least one temperature change.

3. The method according to claim 1, wherein, through the measurement of the at least one pressure drop, the sum of the pressure drops of at least two hydraulic resistance contributions, in particular of at least one consumer component of the molding machine, preferably of a temperature control channel through the mold, of a control cabinet cooling system, of a heat exchanger for an oil cooler, of a tie bar cooling system or of a heat exchanger for a drive train, as well as of at least one control element, is measured and/or calculated, wherein one hydraulic resistance contribution of the at least two hydraulic resistance contributions represents the at least one control element.

4. The method according to claim 1, wherein the at least one pressure drop is measured by in each case one pressure sensor in the feed line and one pressure sensor in the return line and/or the at least one temperature change is measured by in each case one temperature sensor in the feed line and one temperature sensor in the return line.

5. The method according to claim 1, wherein the at least one pressure drop is measured by in each case two pressure sensors arranged in series in terms of flow technology in the at least one temperature control line and/or the at least one temperature change is measured by in each case two temperature sensors arranged in series in terms of flow technology in the at least one temperature control line.

6. The method according to claim 1, wherein the at least one hydraulic resistance and/or the at least one change in resistance of at least one temperature control line to be monitored and to be regulated or to be controlled is calculated from at least two contributions, in particular at least one temperature control channel through the mold and at least one control element.

7. The method according to claim 1, wherein the at least one hydraulic resistance and/or the at least one change in resistance and/or the at least one heat flow and/or the at least one change in heat flow is presented by an output element, preferably a visual display device, particularly preferably a screen.

8. The method according to claim 1, wherein at least one permitted range is defined for the at least one hydraulic resistance and/or for the at least one heat flow of the at least one temperature control line and/or at least one permitted range of change is defined for the at least one change in resistance and/or for the at least one change in heat flow of the at least one temperature control line, and a warning signal is output when the at least one Hydraulic Resistance® and/or the at least one heat flow departs from the at least one permitted range and/or when the at least one change in resistance and/or the at least one change in heat flow departs from the at least one permitted range of change.

9. The method according to claim 8, wherein the warning signal is output visually, in particular through presentation on the screen, and/or in that the warning signal is output acoustically.

10. The method according to claim 8, wherein, for determining the at least one permitted range and/or the at least one permitted range of change before, during and/or after operation, a calculation of the at least one hydraulic resistance and/or of the at least one heat flow is carried out using measured data and/or using data from a simulation and/or using design data, in particular CAD data.

11. The method according to claim 1, wherein at least two temperature control lines are provided, wherein the at least two temperature control lines run through a mold of a molding machine and/or the at least two temperature control lines are connected in parallel.

12. The method according to claim 1, wherein the at least one hydraulic resistance and/or the at least one change in resistance and/or the at least one heat flow and/or the at least one change in heat flow is calculated by the consumer component of the molding machine at least once using measured data and is calculated at least once using data from a simulation or using design data, in particular CAD data, wherein the at least two calculated values of the at least one hydraulic resistance and/or of the at least one change in resistance and/or of the at least one heat flow and/or of the at least one change in heat flow are reconciled in order to discover a deviation or agreement.

13. The method according to claim 12, wherein the reconciliation of the at least two calculated values of the at least one hydraulic resistance and/or the at least one change in resistance takes temperatures and/or temperature differences into consideration.

14. The method according to claim 1, wherein a tubing proposal is created on the basis of absolute values, comparative values, relative values and/or one or more sequences according to size of the hydraulic resistances and/or changes in hydraulic resistance and/or of the heat flows and/or changes in heat flow of the consumer components, wherein consumer components with lower hydraulic resistances and/or low heat flows are connected in series.

15. The method according to claim 14, wherein the tubing proposal is made and/or adapted taking into consideration the measured and/or predetermined temperatures and/or temperature differences of the consumer components.

16. The method according to claim 1, wherein the at least one hydraulic resistance of the at least one temperature control line (i) to be monitored and to be regulated or to be controlled is calculated according to the equations
$${R}_{i} = \frac{Δ p ( δ )}{{Φ}_{i}^{n}}$$
$$Δ p ( δ ) = Δ {p}_{2 i} + Δ {p ( δ )}_{7 i}$$
wherein:
Rᵢ denotes the at least one hydraulic resistance in the at least one temperature control line i to be monitored and to be regulated or to be controlled,
Δp (δ) denotes the at least one pressure drop of the supply system with the at least one temperature control line to be monitored and to be regulated or to be controlled in dependence on the degree of opening δ of the at least one control element,
Φᵢ denotes the at least one volumetric flow rate in the at least one temperature control line i to be monitored and to be regulated or to be controlled,
n denotes a dimensionless characteristic value in dependence on various parameters such as for example the cross section through which the volumetric flow Φi flows and/or the flow conditions, wherein the characteristic value n is approximately 2 in the case of a circular cross section and ideal flow conditions,
Δp₂ᵢ denotes the at least one pressure drop of at least one temperature control channel through the mold in the at least one temperature control line i to be monitored and to be regulated or to be controlled, and
Δp(δ)₇ᵢ denotes the at least one pressure drop in dependence on the degree of opening of the at least one control element in the at least one temperature control line i to be monitored and to be regulated or to be controlled.

17. The method according to claim 16, wherein the at least one hydraulic resistance of a temperature control channel of the mold in the at least one temperature control line (i) to be monitored and to be regulated or to be controlled is calculated according to the equations
$$Δ {p ( δ )}_{7 i} = {R ( δ )}_{7 i} \cdot {Φ}_{i}^{n}$$
$$Δ {p}_{2 i} = Δ p ( δ ) - Δ {p ( δ )}_{7 i}$$
$${R}_{2 i} = \frac{Δ {p}_{2 i}}{{Φ}_{i}^{n}}$$
wherein
Δp(δ)₇ᵢ denotes the at least one pressure drop in dependence on the degree of opening of the at least one control element in the at least one temperature control line i to be monitored and to be regulated or to be controlled,
R(δ)₇ᵢ denotes the at least one hydraulic resistance of the at least one control element in dependence on the degree of opening of the at least one control element in the at least one temperature control line i to be monitored and to be regulated or to be controlled,
Φᵢ denotes the at least one volumetric flow rate in the at least one temperature control line i to be monitored and to be regulated or to be controlled,
n denotes a dimensionless characteristic value in dependence on various parameters such as for example the cross section through which the volumetric flow Φi flows and/or the flow conditions, wherein the characteristic value n is approximately 2 in the case of a circular cross section and ideal flow conditions,
Δp₂ᵢ denotes the at least one pressure drop of at least one temperature control channel through the mold in the at least one temperature control line i to be monitored and to be regulated or to be controlled,
Δp (δ) denotes the at least one pressure drop of the supply system with the at least one temperature control line to be monitored and to be regulated or to be controlled in dependence on the degree of opening δ of the at least one control element and
R₂ᵢ denotes the at least one hydraulic resistance of a temperature control channel through the mold in the at least one temperature control line i to be monitored and to be regulated or to be controlled.

18. The method according to claim 1, wherein the at least one hydraulic resistance R(δ)₇ᵢ of the at least one control element depending on the degree of opening of the at least one control element in the at least one temperature control line i to be monitored and to be regulated or to be controlled is read from a computer-readable storage medium and/or calculated by a processor using an approximation function.

19. The method according to claim 1, wherein a temperature of the temperature control medium is measured and the temperature of the temperature control medium is included in the calculation of the at least one hydraulic resistance.

20. The method for supplying temperature control media to a mold of a molding machine according to claim 1, wherein at least one control element, in particular a volumetric flow valve, is regulated or controlled according to a target value for a pressure of the temperature control medium and/or for a volumetric flow rate of the temperature control medium, wherein the target value is calculated in dependence on the at least one hydraulic resistance R₂ᵢ and/or the at least one change in resistance ΔR₂ᵢ of a temperature control channel through the mold in the at least one temperature control line i to be monitored and to be regulated or to be controlled.

21. The device for supplying temperature control media to a mold of a molding machine with:
a feed line for the central supply of a temperature control medium,
a return line for the central removal of the temperature control medium,
at least one temperature control line, which is connected to the feed line and the return line, for controlling the temperature of the mold,
at least one measuring element, in particular at least one volumetric flow rate measuring element, in each of the temperature control lines actually to be monitored for measuring at least one volumetric flow rate,
at least one control element, in particular at least one volumetric flow valve, in each of the temperature control lines to be regulated or to be controlled for regulating or controlling a volumetric flow rate, and
data processing unit, which is connected to the at least one control element and the at least one measuring element,
wherein:
at least two pressure sensors are provided, which are connected to the data processing unit, for measuring at least one pressure drop,
at least one hydraulic resistance and/or at least one change in resistance of the at least one temperature control line can be calculated by the data processing unit on the basis of the at least one measured volumetric flow rate and on the basis of the at least one measured pressure drop,
the degree of opening of the at least one control element is taken into consideration in the calculation of the at least one hydraulic resistance and/or the at least one change in resistance the at least one hydraulic resistance and/or the at least one change in resistance can be presented by an output element, preferably a visual display device.

22. A device for supplying temperature control media to a mold of a molding machine with:
a feed line for the central supply of a temperature control medium,
a return line for the central removal of the temperature control medium,
at least one temperature control line, which is connected to the feed line and the return line, for controlling the temperature of the mold,
at least one measuring element, in particular at least one volumetric flow rate measuring element, in each of the temperature control lines actually to be monitored for measuring at least one volumetric flow rate,
data processing unit, which is connected to the at least one control element and the at least one measuring element,
wherein:
at least two temperature sensors are provided, which are connected to the data processing unit, for measuring at least one temperature change,
at least one heat flow and/or at least one change in heat flow of the at least one temperature control line can be calculated by the data processing unit on the basis of the at least one measured volumetric flow rate and on the basis of the at least one measured temperature change, and
the at least one heat flow and/or the at least one change in heat flow can be presented by an output element, preferably a visual display device.

23. The device according to claim 21, wherein at least one consumer component of the molding machine, preferably a temperature control channel through the mold, a control cabinet cooling system, a heat exchanger for an oil cooler, a tie bar cooling system or a heat exchanger for a drive train, as well as at least one control element are arranged in series one after the other between at least two pressure sensors.

24. The device according to claim 21, wherein, of the at least two pressure sensors and/or temperature sensors, in each case one pressure sensor and/or one temperature sensor is arranged in the feed line and one pressure sensor and/or one temperature sensor is arranged in the return line.

25. The device according to claim 21, wherein the at least two pressure sensors and/or the at least two temperature sensors are arranged in the at least one temperature control line.

26. The device according to claim 21, wherein the output element, preferably the visual display device, is formed as a screen.

27. The device for data processing comprising means for carrying out the method according to claim 1, in which at least one hydraulic resistance and/or at least one change in resistance is calculated using the at least one measured pressure drop and the regulated or controlled degree of opening of the at least one control element.

28. The device according to claim 21, wherein at least one permitted range for the at least one hydraulic resistance and/or for the at least one heat flow and/or at least one permitted range of change for the at least one change in resistance and/or for the at least one change in heat flow of the at least one temperature control line can be stored in the data processing unit and in that a warning signal can be output when the at least one hydraulic resistance and/or the at least one heat flow departs from the at least one permitted range and/or when the at least one change in resistance and/or the at least one change in heat flow departs from the at least one range of change.

29. The device according to claim 28, wherein the warning signal can be output visually, in particular through presentation on the screen, and/or in that the warning signal can be output acoustically.

30. The device according to claim 28, wherein the molding machine can be switched off by the data processing unit when the warning signal is output.

31. The device according to claim 21, wherein a data processing unit calculates the at least one hydraulic resistance of the at least one temperature control line (i) to be monitored and to be regulated or to be controlled according to the equations:
$${R}_{i} = \frac{Δ p ( δ )}{{Φ}_{i}^{n}}$$
$$Δ p ( δ ) = Δ {p}_{2 i} + Δ {p ( δ )}_{7 i}$$
wherein:
Rᵢ denotes the at least one hydraulic resistance in the at least one temperature control line i,
Δp(δ) denotes the at least one pressure drop of the supply system with the at least one temperature control line in dependence on the degree of opening δ of the at least one control element, Φᵢ denotes the at least one volumetric flow rate in the at least one temperature control line i,
n denotes a dimensionless characteristic value in dependence on various parameters such as for example the cross section through which the volumetric flow Φi flows and/or the flow conditions, wherein the characteristic value n is approximately 2 in the case of a circular cross section and ideal flow conditions,
Δp₂ᵢ denotes the at least one pressure drop of at least one temperature control channel through the mold in the at least one temperature control line I, and
Δp(δ)₇ᵢ denotes the at least one pressure drop in dependence on the degree of opening of the at least one control element in the at least one temperature control line i.

32. The device according to claim 21, wherein a data processing unit calculates the at least one hydraulic resistance of the at least one mold in the at least one temperature control line (i) to be monitored and to be regulated or to be controlled according to the equations
$$Δ {p ( δ )}_{7 i} = {R ( δ )}_{7 i} \cdot {Φ}_{i}^{n}$$
$$Δ {p}_{2 i} = Δ p ( δ ) - Δ {p ( δ )}_{7 i}$$
$${R}_{2 i} = \frac{Δ {p}_{2 i}}{{Φ}_{i}^{n}}$$
wherein:
Δp(δ)₇ᵢ denotes the at least one pressure drop in dependence on the degree of opening of the at least one control element in the at least one temperature control line i,
R(δ)₇ᵢ denotes the at least one hydraulic resistance of the at least one control element in dependence on the degree of opening of the at least one control element in the at least one temperature control line i,
Φᵢ denotes the at least one volumetric flow rate in the at least one temperature control line i,
n denotes a dimensionless characteristic value in dependence on various parameters such as for example the cross section through which the volumetric flow Φi flows and/or the flow conditions, wherein the characteristic value n is approximately 2 in the case of a circular cross section and ideal flow conditions,
Δp₂ᵢ denotes the at least one pressure drop of at least one temperature control channel through the mold in the at least one temperature control line i,
Δp(δ) denotes the at least one pressure drop of the supply system with the at least one temperature control line in dependence on the degree of opening δ of the at least one control element, and
R₂ᵢ denotes the at least one hydraulic resistance of a temperature control channel through the mold in the at least one temperature control line i.

33. The device according to claim 21 with at least one control element, in particular a volumetric flow valve, which is connected to a control or regulating device for controlling or regulating the control element according to a target value for a pressure of the temperature control medium and/or for a volumetric flow rate of the temperature control medium, wherein the target value is calculated in dependence on the at least one hydraulic resistance R₂ᵢ and/or the at least one change in resistance ΔR₂ᵢ of a temperature control channel through the mold in the at least one temperature control line i to be monitored and to be regulated or to be controlled.

34. The device according to claim 21, wherein a temperature sensor, connected to the data processing unit, for measuring a temperature of the temperature control medium is provided and in that the at least one hydraulic resistance can be calculated on the basis of the temperature.

35. A computer program product, comprising commands which, when the program is executed by a computer, prompt the latter to carry out the method of claim 1.

36. A computer-readable storage medium comprising commands which, when executed by a computer, prompt the latter to carry out the method of claim 1.

37. A computer-readable data carrier on which the computer program product according to claim 35 is stored.

38. A data carrier signal, which transmits the computer program product according to claim 35.

39. A molding machine, in particular injection-molding machine, with a device according to claim 21.
